(19) United States
(12) Patent Application Publication
(10) Pub. No.: US 2024/0124698 A1
(43) Pub. Date: Apr. 18, 2024

(54) COMPOSITION, AS WELL AS METAL-CLAD LAMINATE AND METHOD FOR ITS PRODUCTION

(71) Applicant: AGC Inc., Tokyo (JP)

(72) Inventors: Motoshi ONO, Tokyo (JP); Kanji ARAI, Tokyo (JP)

(73) Assignee: AGC Inc., Tokyo (JP)

(21) Appl. No.: 18/527,512

(22) Filed: Dec. 4, 2023

Related U.S. Application Data
(63) Continuation of application No. PCT/JP2022/022650, filed on Jun. 3, 2022.

(30) Foreign Application Priority Data
Jun. 11, 2021 (JP) 2021-097909

(51) Int. Cl. C08L 27/12; B05D 7/14; C08K 3/22; C08K 3/36

(52) U.S. Cl. CPC C08L 27/12; B05D 7/14; C08K 3/22; C08K 3/36; B05D 2202/45; B05D 2506/10; C08K 2003/2237; C08K 2201/005; C08L 2205/025

(57) ABSTRACT

To provide a composition whereby it is possible to obtain a metal-clad laminate having low relative permittivity and dissipation factor and having adhesion of the composition layer to the metal layer improved, as well as the metal-clad laminate comprising a composition layer made of the composition, and a method for its production. A composition comprising a fluorinated polymer A1 containing units based on a fluoroolefin and units based on a monomer having an adhesive functional group, and an inorganic filler having a specific surface area of less than 5.5 m²/g, wherein the content of the inorganic filler in the solid content of the composition is at least 55 vol % to the entire volume of the solid content of the composition.

### TECHNICAL FIELD

The present invention relates to a composition as well as a metal-clad laminate and a method for its production.

### BACKGROUND ART

In recent years, in various types of electronic devices, along with an increase of the volume of information processing, mounting technologies such as higher integration of mounted semiconductor devices, denser wiring, and multilayering, have been rapidly advancing. In order to reduce dielectric loss, the substrate materials used to make up the substrates for printed wiring boards to be used in various electronic devices are required to have low relative permittivity and dissipation factor.

In response to such requirements, it has been proposed to use a composition containing a fluororesin excellent in dielectric properties (i.e. low relative permittivity and dissipation factor) among resin materials, for the core portion of a copper clad laminate (CCL). However, when a fluororesin is used for the core portion of a copper clad laminate, although the dielectric properties are good, there has been a problem that the adhesion to the copper foil is low.

Therefore, in order to improve the adhesion (metal foil peel strength) of such a composition containing a fluororesin to a copper foil, there have been such attempts that the surface roughness of the copper foil is increased to obtain an anchor effect (see, for example, Patent Document 1), an adhesive layer (primer layer) is provided between the composition layer made of the composition containing the fluororesin and the copper foil (see, for example, Patent Document 2), and the surface of the composition layer made of the composition containing the fluororesin is activated by plasma treatment (see, for example, Patent Document 3).

### Prior Art Documents

### Patent Documents

Patent Document 1: Japanese Patent No. 2861172
Patent Document 2: JP-A-2007-98692
Patent Document 3: JP-A-2017-2115

### DISCLOSURE OF INVENTION

### Technical Problem

However, in the above-mentioned Patent Document 1, there may be a case where the transmission loss of the metal-clad laminate becomes large. Also, in the above-mentioned Document 2, the dielectric loss of the adhesive layer is large, whereby there may be a case where it is not possible to obtain a metal-clad laminate having a reduced dissipation factor. Further, in the above-mentioned Document 3, the resin layer is subjected to plasma treatment, whereby there may be a case where the composition layer material undergoes embrittlement.

From the foregoing, there is a strong need for the development of a composition capable of forming a metal-clad laminate having low relative permittivity and dissipation factor and having adhesion of the resin layer to the metal foil improved.

In view of the above problem, the present invention is to provide a composition whereby a metal-clad laminate having low relative permittivity and dissipation factor and having adhesion of the composition layer to a metal layer improved, as well as a metal-clad laminate comprising a composition layer made of the composition and a method for its production.

### Solution to Problem

As a result of diligent study to solve the above problem, the present inventors have found that by mixing a fluorinated polymer A1 which is an adhesive fluororesin, and an inorganic filler having specific properties in a specific ratio, it is possible to solve the above problem, and thus, have completed the present invention.

Here, when the fluorinated polymer A1 which is an adhesive fluororesin, and an inorganic filler having specific properties are mixed in a specific ratio, the adhesiveness of the composition layer to the metal layer is improved, and the reason for the improvement is assumed to be such that the viscosity in the case of applying the composition to the metal layer becomes suitable and voids tend to less likely to occur in the metal layer/fluorinated polymer A1/inorganic filler.

That is, the present invention is as follows.
[1] A composition comprising a fluorinated polymer A1 containing units based on a fluoroolefin and units based on a monomer having an adhesive functional group, and an inorganic filler having a specific surface area of less than 5.5 m²/g, wherein the content of the inorganic filler in the solid content of the composition is at least 55 vol % to the entire volume of the solid content of the composition.
[2] The composition according to [1], which further comprises a fluorinated polymer A2 containing units based on a fluoroolefin and not containing units based on a monomer having an adhesive functional group.
[3] The composition according to [2], wherein the content of the fluorinated polymer A2 is at least 10 vol % to the total of the fluorinated polymer A1 and the fluorinated polymer A2.
[4] The composition according to any one of [1] to [3], wherein the adhesive functional group is at least one type selected from the group consisting of a carbonyl group, a hydroxy group, an epoxy group, an amide group, an amino group and an isocyanate group.
[5] The composition according to any one of [1] to [4], wherein the inorganic filler is at least one of silicon oxide and titanium oxide.
[6] The composition according to any one of [1] to [5], wherein the inorganic filler has a sphericity of at least 0.80.
[7] The composition according to any one of [1] to [6], wherein the median diameter (average particle size D50) of the inorganic filler is less than 20 μm.
[8] The composition according to any one of [1] to [7], wherein the content of the inorganic filler in the solid content of the composition is at most 85 vol % to the entire volume of the solid content of the composition.
[9] The composition according to any one of [1] to [8], wherein the surface adsorbed moisture content of the inorganic filler is at most 500 mass ppm.
[10] A metal-clad laminate, comprising a composition layer made of the composition as defined in any one of [1] to [9], and a metal layer.
[11] The metal-clad laminate according to [10], which further comprises an adhesive layer containing the fluorinated polymer A1 and containing no inorganic filler having a specific surface area of less than 5.5 m²/g.
[12] The metal-clad laminate according to [11], wherein the adhesive layer further contains an inorganic filler having a specific surface area of at least 5.5 m²/g, and the content of the inorganic filler to the entire volume of the adhesive layer is at most 85 vol % to the entire volume of the adhesive layer.
[13] The metal-clad laminate according to any one of [10] to [12], wherein the metal layer is a layer made of a copper foil.
[14] The metal-clad laminate according to any one of [10] to [13], wherein the ten-point average roughness (Rzjis) of the surface on the composition layer side of the metal layer is at most 2.0 μm.
[15] A method for producing a metal-clad laminate, which comprises applying the composition as defined in any one of [1] to [9] to the surface of a metal layer to obtain a metal-clad laminate.

### Advantageous Effects of Invention

According to the present invention, it is possible to provide a composition whereby a metal-clad laminate having low relative permittivity and dissipation factor and having adhesion of the composition layer to the metal layer improved, can be obtained, as well as a metal-clad laminate comprising a composition layer made of the composition, and a method for its production.

### BRIEF DESCRIPTION OF DRAWINGS

FIG. 1 is a schematic cross-sectional view illustrating an example of the metal-clad laminate of the present invention.

FIG. 2 is a schematic cross-sectional view illustrating another example of the metal-clad laminate of the present invention.

FIG. 3 is a schematic cross-sectional view illustrating still another example of the metal-clad laminate of the present invention.

FIG. 4 is a schematic cross-sectional view illustrating an example of a resin-attached metal foil to be used at the time of producing a metal-clad laminate of the present invention.

FIG. 5 is a schematic cross-sectional view illustrating an example of a wiring substrate produced by using the metal-clad laminate of the present invention.

### DESCRIPTION OF EMBODIMENTS

In the following, the present invention will be described in detail.

In this specification, the preferred provisions can be adopted arbitrarily, and combinations of preferred ones can be said to be more favorable.

In this specification, the phrase “XX to YY” means “at least XX and at most YY”.

In this specification, the lower and upper limit values listed stepwisely in the preferred numerical ranges (e.g. ranges of content, etc.) can be independently combined. For example, from the description “preferably from 10 to 90, more preferably from 30 to 60”, the “preferred lower limit vale (10)” and the “more preferred upper limit value (60)” can be combined to “from 10 to 60”. Further, in the numerical value ranges described in this specification, the upper or lower limit values in the numerical value ranges may be replaced by the values shown in Examples.

In this specification, a “unit based on a monomer” is a generic term for an atomic group directly formed by polymerization of a single monomer molecule and an atomic group obtained by chemical conversion of a portion of this atomic group. Hereinafter, units based on a monomer A may be referred to also as monomer A units.

In this specification, “not containing units based on a monomer having an adhesive functional croup” means that “the content of monomer units having adhesive functional groups is less than 0.05 mol %, preferably less than 0.03 mol %, more preferably less than 0.01 mol %, to all units contained in the polymer”.

In this specification, “solid content of the composition” means, if the composition is a slurry containing a solvent, the components constituting the composition layer other than the solvent.

In this specification, the content of the polymer A1 (vol %), the content of the polymer A2 (vol %), and the content of the inorganic filler (vol %) to the entire volume of the “composition layer, adhesive layer, or intermediate layer” are determined by measuring the respective masses of the polymer A1 the polymer A2, and the inorganic filler before they are mixed (formulated), and are obtained by volume conversion from their respective specific gravities.

### (Composition)

The composition of the present invention comprises a fluorinated polymer A1 and an inorganic filler, and further comprises a fluorinated polymer A2, a thermoplastic elastomer, a solvent and other components as the case requires.

In the following, the respective components of the composition of the present invention will be described specifically.

<Fluorinated polymer A1>

The fluorinated polymer A1 comprises units based on a fluoroolefin and units based on a monomer having an adhesive functional group, and, as the case requires, may have units based on a monomer other than the fluoroolefin and the monomer having an adhesive functional group.

### <<Units Based on a Fluoroolefin>>

As the “fluoroolefin” in the “units based on a fluoroolefin”, for example, tetrafluoroethylene (hereinafter referred to as “TFE”), chlorotrifluoroethylene (hereinafter referred to as “CTFE”), trifluoroethylene, vinyl fluoride, vinylidene fluoride (fluorinated vinylidene (hereinafter referred to as “VdF”)), hexafluoropropylene (hereinafter referred to as “HFP”), a perfluoroalkyl vinyl ether represented by CF₂═CFOR^{f1} (where R^{f1} is a C₁₋₁₀ perfluoroalkyl group which may contain an oxygen atom between carbon atoms), CF₂═CFOR^{f2}SO₂X¹ (R^{f2} is a C₁₋₁₀ perfluoroalkylene group which may contain an oxygen atom between carbon atoms, and X¹ is a halogen atom or a hydroxy group), CF₂═CFOR^{f2}CO₂X² (where R^{f2} is the same as defined above, X² is a hydrogen atom or a C₁₋₃ alkyl group), CF₂═CF(CF₂)ₚOCF═CF₂ (where p is 1 or 2), CH₂CX³ (CF₂)_{q}X⁴ (where X³ and X⁴ are each independently a hydrogen atom or a fluorine atom, and q is an integer of from 2 to 10), perfluoro(2-methylene-4-methyl-1,3-dioxolane), etc. may be mentioned. One type of these may be used alone, or two or more types of these may be used in combination. Among these, tetrafluoroethylene and a perfluoroalkyl vinyl ether are preferred, from such a viewpoint that their dissipation factor is low.

As specific examples of the perfluoroalkyl vinyl ether, for example, CF₂═CFOCF₂CF₃, CF₂═CFOCF₂CF₂CF₃, CF₂═CFOCF₂CF₂CF₂CF₃, CF₂═CFO(CF₂)₈F, etc. may be mentioned. One type of these may be used alone, or two or more types of these may be used in combination. Among these, CF₂═CFOCF₂CF₂CF₃ is preferred.

As specific examples of CH₂═CX³(CF₂)_{q}X⁴, for example, CH₂═CH(CF₂)₂F, CH₂═CH(CF₂)₃F, CH₂═CH(CF₂)₄F, CH₂═CF(CF₂)₃H, CH₂═CF(CF₂)₄H, etc. may be mentioned.

Although there is no restriction as to the content of units based on a fluoroolefin in the fluorinated polymer A1, it is preferably from 90.0 to 99.9 mol %, more preferably from 95.0 to 99.8 mol%, particularly preferably from 97.0 to 99.7 mol %, to the total molar amount of all units in the fluorinated polymer A1. When the content of units based on a fluoroolefin is in the above preferred range, it is possible to obtain a composition layer with low relative permittivity and dissipation factor.

### <<Units Based on a Monomer Having an Adhesive Functional Group>>

As an “adhesive functional group” in a “monomer having an adhesive functional group”, for example, a carbonyl group, a hydroxy group, an epoxy group, an amide group, an amino group, an isocyanate group, etc. may be mentioned. One type of these may be used alone, or two or more types of these may be used in combination. Among these, a carbonyl group is preferred from the viewpoint of superior adhesion of the composition layer to the metal layer.

As the “monomer having an adhesive functional group”, for example, a cyclic hydrocarbon monomer having a dicarboxylic anhydride group and a polymerizable unsaturated group in the ring (hereinafter simply referred to as a “cyclic hydrocarbon monomer”) may suitably be mentioned.

The above “cyclic hydrocarbon monomer” refers to a polymerizable compound that is a cyclic hydrocarbon consisting of at least one 5- or 6-membered ring and that also has a dicarboxylic anhydride group and an unsaturated group that is polymerizable in the ring. As the cyclic hydrocarbon, a cyclic hydrocarbon having at least one bridged polycyclic hydrocarbon is preferred. That is, a cyclic hydrocarbon consisting of a bridged polycyclic hydrocarbon, a cyclic hydrocarbon in which at least two bridged polycyclic hydrocarbons are condensed, or a cyclic hydrocarbon in which a bridged polycyclic hydrocarbon and another cyclic hydrocarbon are condensed, is preferred.

Further, the cyclic hydrocarbon monomer has at least one intracyclic polymerizable unsaturated group, i.e. polymerizable unsaturated group that exists between carbon atoms constituting the hydrocarbon ring, The cyclic hydrocarbon monomer further has a dicarboxylic anhydride group (—CO—O—CO—), which may be bonded to two carbon atoms constituting the hydrocarbon ring or may be bonded to two carbon atoms outside the ring. Preferably, the dicarboxylic anhydride group is bonded to two adjacent carbon atoms constituting the ring of the above-mentioned cyclic hydrocarbon. Furthermore, to the carbon atoms constituting the ring of the cyclic hydrocarbon, instead of a hydrogen atom, a halogen atom, an alkyl group, an alkyl halide group, or other substituent may be bonded.

Its specific examples are those represented by the following formulae (1) to (8). Here, R in the formulae (2), (5) to (8) represents a C₁₋₆ lower alkyl group; a halogen atom selected from a fluorine atom, a chlorine atom, a bromine atom and an iodine atom; or an alkyl halide group having a hydrogen atom in the above lower alkyl group substituted by a halogen atom.

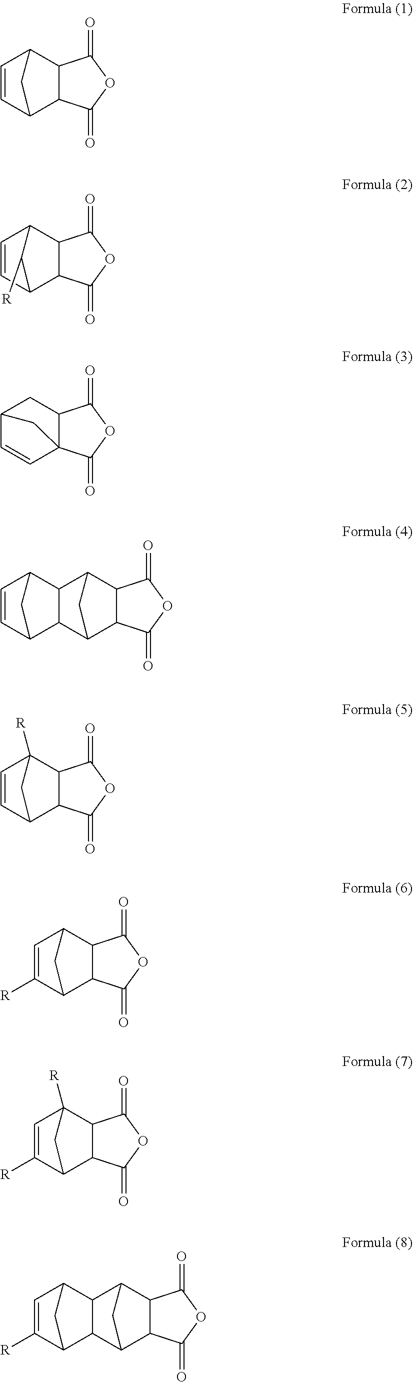

As the above cyclic hydrocarbon monomer, preferred are a 5-norbornene-2,3-dicarboxylic anhydride (hereinafter referred to as “NAH”) represented by the formula (1); cyclic hydrocarbon monomers being acid anhydrides represented by the formulae (3) and (4); and cyclic hydrocarbon monomers of the formula (2) and the formulae (5) to (8) in which the substituent R is a methyl group; and more preferred is NAH.

There is no particular restriction on the content of units based on a monomer having an adhesive functional group in the fluorinated polymer A1, but it is preferably from 0.01 to 5 mol %, more preferably from 0.03 to 3 mol %, particularly preferably from 0.05 to 2 mol %, to the total molar amount of all units in the fluorinated polymer A1. When the content of units based on a monomer having an adhesive functional group is within the above preferred range, it is possible to obtain a composition layer excellent in adhesion to the metal layer.

### <<Units Based on Other Monomer>>

As other monomer, for example, a C₂₋₄ olefin such as ethylene, propylene or isobutene; a vinyl ester such as vinyl acetate; a vinyl ether such as ethyl vinyl ether or cyclohexyl vinyl ether; etc. may be mentioned. One type of these may be used alone, or two or more types of these may be used in combination.

There is no particular restriction on the content of units based on other monomer in the fluorinated polymer A1, but it is preferably from 0.1 to 10 mol %, more preferably from 0.5 to 5 mol %, particularly preferably from 1 to 3 mol %, to the total molar amount of all units in the fluorinated polymer A1.

The adhesion of the composition layer to the metal layer can be improved as the fluorinated polymer A1 contains units based on a fluoroolefin and units based on a monomer having an adhesive functional group.

As specific examples of the fluorinated polymer A1, for example, a TFE/CF₂═CFOCF₂CF₂CF₃/NAH copolymer, a TFE/HFP/NAH copolymer, a TFE/CF₂═CFOCF₂CF₂CF₃/HFP/NAH copolymer, a TFE/VdF/NAH copolymer, a TFE/CH₂═CH(CF₂)₄F/NAH/ethylene copolymer, a TFE/CH₂═CH(CF₂)₂F/NAH/ethylene copolymer, a CTFE/CH₂═CH(CF₂)₄F/NAH/ethylene copolymer, a CTFE/CH₂═CH(CF₂)₂F/NAH/ethylene copolymer, a CTFE/CH₂═CH(CF₂)₂F/NAH/ethylene copolymer, etc. may be mentioned. One type of these may be used alone, or two or more types of these may be used in combination. Among these, a TFE/CF₂═CFOCF₂CF₂CF₃/NAH copolymer is preferred from the viewpoint of easy production.

There is no particular restriction as to the melting point of the fluorinated polymer A1, and it is preferably at least 150° C. and at most 320° C., more preferably at least 200° C. and at most 310° C. The melting point can be adjusted by appropriately selecting the content ratio of units based on a fluoroolefin, units based on a monomer having an adhesive functional group and units based on other monomer.

As the volumetric flow velocity (hereinafter referred to as Q value) of the fluorinated polymer A, there is no particular restriction, and it is preferably from 5 to 500 mm³/sec, more preferably from 10 to 200 mm³/sec. The Q value is an index representing the melt flowability of the fluorinated polymer A1, and will be a guide to the molecular weight. The larger the Q value, the lower the molecular weight, and the smaller the Q value, the higher the molecular weight.

The Q value is the extrusion speed of the fluorinated polymer A1 when it is extruded through an orifice of 2.1 mm in diameter and 8 mm in length under a load of 7 kg at a temperature higher by 50° C. than the melting point of the fluorinated polymer A1, using a Shimadzu flow tester. If this Q value is too small, molding becomes difficult. Conversely, if it is too large, the mechanical strength of the fluorinated polymer A1 decreases.

The production method for the fluorinated polymer A1 is not particularly limited, and it can be produced by a known method.

The fluorinated polymer A1 obtained by the known production method can be obtained in the form of pellets, powder or any other form according to the regular method. Since this fluorinated polymer A1 is excellent in moldability, it can be injection molded, extrusion molded or press molded, and can be formed into a desired shape.

The fluorinated polymer A1 can be produced as described above, but a commercial product can be used. There is no particular restriction on the commercial product of the fluorinated polymer A1, but, for example, EA-2000 manufactured by AGO Inc. may be mentioned.

As the content of the fluorinated polymer A1 in the solid content of the composition of the present invention, there is no particular restriction so long as it s at most 45 vol %, to the entire volume of the solid content of the composition, but from the viewpoint of the thermal expansion coefficient and mechanical strength, it is preferably from 15 to 45 vol %, more preferably from 20 to 40 vol %, particularly preferably from 30 to 40 vol %.

When the content of the fluorinated polymer A1 in the solid content of the composition of the present invention is within the above preferred range, the adhesiveness of the composition layer to the metal layer can be improved without impairing the strength of the substrate.

### <Inorganic Filler>

As the inorganic filler, for example, a silicon oxide such as spherical silica; a metal oxide such as titanium oxide, alumina or mica; a metal hydroxide such as aluminum hydroxide or magnesium hydroxide; talc; aluminum borate; barium sulfate; or calcium carbonate; may be mentioned.

The inorganic filler may be hollow inorganic microspheres such as glass microspheres or ceramic microspheres.

The glass microspheres are preferably ones containing silica glass or borosilicate glass.

The ceramic microspheres are preferably ones containing barium titanate and particularly preferably ones containing barium titanate doped with neodymium or zinc oxide.

The hollow inorganic microspheres may be non-porous or porous, crystalline or non-crystalline.

The hollow inorganic microspheres are preferably hydrophobic as coating treated by e.g. a silane coupling agent such as phenyltrimethoxysilane, phenyltriethoxysilane, (3,3,3-trifluoropropyl)trimethoxysilane, (tridecafluoro-1,1,2,2-tetrahydrooctyl)-1,1-triethoxysilane or (heptadecafluoro-1,1,2,2-tetrahydrodecyl)-1-triethoxysilane; a zirconate such as neopentyl(diaryl)oxytri(dioctyl)pyrophosphate zirconate or neopentyl(diaryl)oxytri(N-ethylenediamino)ethyl zirconate; or a titanate such as neopentyl(diaryl)oxytrineodecanoyl titanate, neopentyl(diaryl)oxytri(dodecyl)benzene-sulfonyl titanate or neopentyl(diaryl)oxytri(dioctyl)phosphate titanate.

One type of these may be used alone, or two or more types of these may be used in combination. Among these, silicon oxide or titanium oxide is preferred from the viewpoint of the low thermal expansion properties, and spherical silica is more preferred.

As the specific surface area of the inorganic filler, there is no particular restriction so long as it is less than 5.5 m ²/g, but it is preferably less than 4.5 m²/g, more preferably less than 3.5 m²/g, particularly preferably less than 3.0 m²/g.

When the specific surface area of the inorganic filler is within the above preferred range, the adhesion of the composition layer to the metal layer becomes to be sufficient.

Here, the “specific surface area” is measured by the same method as in Examples.

There is no particular restriction on the sphericity of the inorganic filler, but it is preferably at least 0.80, more preferably at least 0.83, particularly preferably at least 0.85.

When the sphericity of the inorganic filler is within the above preferred range, through-hole plating quality can be improved.

Here, the “sphericity” is measured by the same method as in Examples.

As the median diameter (average particle diameter D50) of the inorganic filler, there is no particular restriction, but it is preferably less than 20 μm, more preferably less than 15 μm, particularly preferably less than 10 μm.

When the median diameter (average particle diameter D50) of the inorganic filler is within the above preferred range, the homogeneity and drillability of the composition layer will be excellent.

Here, the “median diameter (average particle diameter D50)” is measured by be same method as in Examples.

There is no particular restriction on the amount of moisture adsorbed on the surface of the inorganic filler, but it is preferably at most 500 mass ppm, more preferably at most 400 mass ppm, particularly preferably at most 300 mass ppm.

When the amount of moisture adsorbed on the surface of the inorganic filler is within the above preferred range, the dissipation factor of the composition layer can be made to be low.

Here, the “amount of moisture adsorbed on the surface” is measured by the same method as in Examples.

As the content of the inorganic filler in the solid content of the composition, there is no particular restriction so long as it is at least 55 vol % to the entire volume of the solid content of the composition, but from the viewpoint of controlling the thermal expansion coefficient of the composition layer, it is preferably at least 63 vol %, more preferably at least 65 vol %. It is preferred to increase the content of the inorganic filler, since it is thereby possible to reduce the rigidity of the composition layer and the after-described coefficient of thermal expansion CTE, to be smaller.

Further, although there is no particular restriction on the upper limit value of the content of the inorganic filler in the solid content of the composition, it is preferably at most 85 vol %, more preferably at most 75 vol %, particularly preferably at most 73 vol %, from the viewpoint of controlling the thermal expansion coefficient of the composition layer.

### <Fluorinated Polymer A2>

The fluorinated polymer A2 as an optional component, contains units based on a fluoroolefin, does not contain units based on a monomer having an adhesive functional group and may contain units based on a monomer other than the fluoroolefin and a monomer having an adhesive functional group.

Here, the “units based on a fluoroolefin”, “units based on a monomer having an adhesive functional group” and “units based on other monomer” are as described in the section for the “Fluorinated polymer A1”.

There is no particular restriction as to the content of the units based on a fluoroolefin in the fluorinated polymer A2, but it is preferably from 90 to 100 mol %, more preferably from 95 to 100 mol %, particularly preferably from 97 to 100 mol %, to the total molar amount of all units in the fluorinated polymer A2. When the content of units based on a fluoroolefin is in the above preferred range, it is possible to obtain a composition layer with low relative permittivity and dissipation factor.

As the content of units based on other monomer in the fluorinated polymer A2, there is no particular restriction, but it is preferably from 0 to 10 mol %, more preferably from 0 to 5 mol %, particularly preferably from 0 to 3 mol %, to the total molar amount of all units in the fluorinated polymer A2.

The dissipation factor of the composition layer can be made to be low by letting the fluorinated polymer A2 contain units based on a fluoroolefin and not contain units based on a monomer having an adhesive functional group.

As the fluorinated polymer A2, a commercial product may be used, There is no particular restriction on the commercial product of the fluorinated polymer A2, but, for example, Fluon FL1710, manufactured by AGC Inc. may be mentioned.

In a case where the fluorinated polymer A2 is contained, the content of the fluorinated polymer A2 is not particularly restricted, but it is preferably at least 10 vol %, more preferably from 20 to 80 vol %, particularly preferably from 40 to 70 vol %, to the total of the fluorinated polymer A1 and the fluorinated polymer A2.

When the content of the fluorinated polymer A2 is within the above preferred range, the fluorine units become increased, whereby it is possible to further improve the dissipation factor.

### <Solvent>

As the solvent being an optional component, for example, toluene, xylene, methyl ethyl ketone, methyl isobutyl ketone, cyclohexanone, ethyl acetate, butyl acetate, dimethyl formamide, dimethylacetamide and N-methyl pyrrolidone may be mentioned. One of these may be used alone, or two or more of these may be used in combination. Among these, toluene, methyl ethyl ketone, N-methyl pyrrolidone and cyclohexanone are preferred from the viewpoint of solubility and handling efficiency of the composition.

In a case where the composition of the present invention contains a solvent, there is no particular restriction as to the content of the solvent in the composition of the present invention, but it is preferably from 50 to 400 parts by mass, more preferably from 100 to 300 parts by mass, particularly preferably from 150 to 250 parts by mass, to 100 parts by mass of the fluorinated polymer A1.

When the content of the solvent is at least the above lower limit value, handling efficiency of the composition will be good, and when it is at most the above upper limit value, a composition layer with a predetermined thickness will be obtained.

### <Other Component>

As other component being an optional component, for example ; a surfactant; an antifoamer such as a silicone antifoamer or an acrylic ester antifoamer; a heat stabilizer; an antistatic agent; an UV absorber; a dye; a pigment; a lubricant; a dispersant such as a wetting and dispersing agent; etc. may be mentioned. One type of these may be used alone, or two or more types of these may be used in combination. Among these, a surfactant is preferred from the viewpoint of mechanical properties,

### <<Surfactant>>

As the surfactant, for example, a nonionic fluorinated surfactant, a silicone surfactant, a hydrocarbon surfactant, etc. may be mentioned. One type of these may be used alone, or two or more types of these may be used in combination. Among these, a nonionic fluorinated surfactant is preferred from the viewpoint of dispersibility of the fluorinated polymer A1.

In a case where the composition of the present invention contains a surfactant, there is no particular restriction as to the content of the surfactant, and it is preferably from 5 to 30 parts by mass, more preferably from 10 to 20 parts by mass, to 100 parts by mass of the fluorinated polymer A1.

Further, the composition of the present invention will be cured to become the after-described composition layer, for example, by heating the composition at from 330 to 380° C. for from 5 to 60 minutes.

### (Metal-Clad Laminate)

The metal-clad laminate of the present invention comprises a composition layer made of the composition of the present invention and a metal layer, and further comprises an adhesive layer and an intermediate layer, as the case requires.

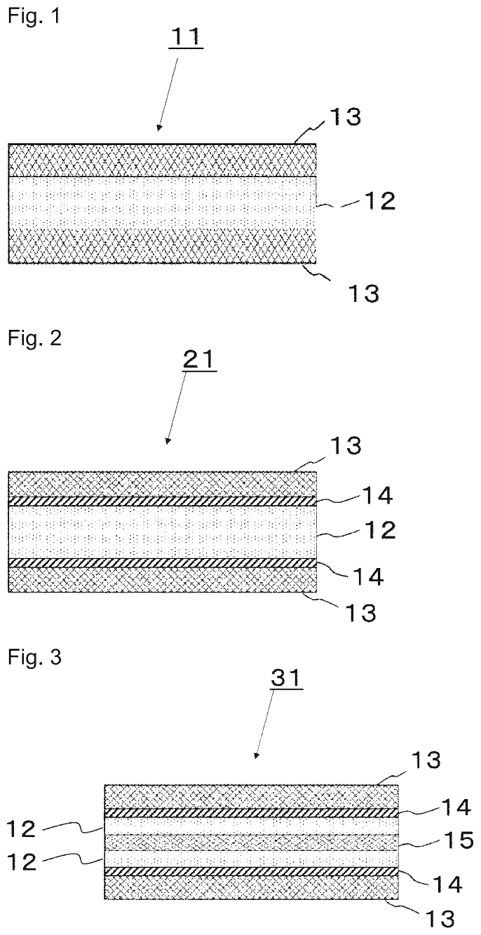

FIG. 1 is a schematic cross-sectional view illustrating an example of the metal-clad laminate of the present invention.

As shown in FIG. 1, the metal-clad laminate 11 has a composition layer (insulating layer) 12 made of the composition of the present invention and metal layers 13 disposed on both sides of the composition layer (insulating layer) 12.

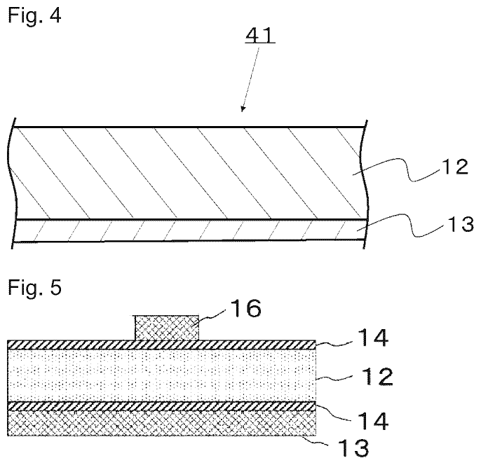

Here, the metal-clad laminate of the present invention may be, as shown in FIG. 1, a double-sided metal foil-clad laminate in which the metal layers 13 are arranged on both sides of the composition layer 12, or it may be a single-sided metal foil-clad laminate in which the metal layer 13 is arranged on one side of the composition layer 12 (see FIG. 4, as described later). Further, the metal-clad laminate of the present invention may have a structure in which a plurality of a laminate structure consisting of a metal layer 13 and a composition layer 12 are laminated. Here, a single-sided metal foil-clad laminate that uses a copper foil as the metal layer 13 is called a resin coated copper foil (RCC), while a double-sided metal foil-clad laminate that uses a copper foil as the metal layer 13 is called a copper clad laminate (CCL).

In the metal-clad laminate of the present invention, the coefficient of thermal expansion CTE of the composition layer is preferably from 10 to 25 ppm/° C.

Here, for the coefficient of thermal expansion CTE (ppm/QC), the coefficient of thermal expansion CTE at a temperature below the glass transition temperature was measured with respect to a sample for evaluation (composition layer) by using a thereto-mechanical analyzer (TMA402FA Hyperion, manufactured by NETZSCH). Further, the coefficient of thermal expansion CTE below the glass transition temperature was performed in the range of −20° C. to 240° C. at a temperature increase rate of 5° C./min.

According to the above-described construction, it is possible to obtain a metal-clad laminate capable of preparing a substrate having the dielectric loss sufficiently reduced.

FIG. 2 is a schematic cross-sectional view of another example of the metal-clad laminate of the present invention.

As shown in FIG. 2, the metal-clad laminate 21 has a composition layer 12 made of the composition of the present invention, metal layers 13 disposed on both outer surfaces of the composition layer 12, and adhesive layers (primer layers) 14 disposed between the composition layer 12 and the metal layers 13. That is, the metal-clad laminate 21 has the metal layers 13, the adhesive layers 14 and the composition layer 12 in this order, and the adhesive layers 14 are provided on the surfaces of the metal layers 13 and the composition layer 12 is provided on the surfaces of the adhesive layers 14.

FIG. 3 is a schematic cross-sectional view of yet another example of the metal-clad laminate of the present invention.

As shown in FIG. 3, the metal-clad laminate 31 is similar to the metal-clad laminate 21 in FIG. 2, except that it has an additional intermediate layer 15 that divides the composition layer 12 into two parts.

### <Composition Layer>

The composition layer is a layer consisting of the composition of the present invention.

The thickness of the composition layer is not particularly limited, but from the viewpoint of preventing disconnection of circuit wiring due to deformation or bending, it is preferably at least 50 μm, more preferably at least 70 μm, particularly preferably at least 100 μm.

Further, the thickness of the composition layer is not particularly limited, but from the viewpoint of flexibility, miniaturization and weight reduction of the wiring substrate to be prepared, it is preferably at most 300 μm, more preferably at most 200 μm, particularly preferably at most 150 μm.

Further, the dissipation factor Df of the composition layer at a frequency of 10 GHz is, from the viewpoint of suppressing transmission loss, preferably at most 0.0020, more preferably at most 0.0015, particularly preferably at most 0.0010.

Here, the “dissipation factor Df” is measured by the same method as in Examples.

The relative permittivity Dk of the composition layer at a frequency of 10 GHz is preferably at least 2.0, more preferably at least 2.2, particularly preferably at least 2.4, from the viewpoint of easy production and widening the range of options.

Further, as the relative permittivity Dk of the composition layer at a frequency of 10 GHz, it is preferably at most 4.0, more preferably at most 3.5, particularly preferably at most 3.2, from the viewpoint of suppressing transmission loss.

Here, the “relative permittivity Dk” is measured by the same method as in Examples.

### <Metal Layer>

As the metal layer, for example, a conductive metal foil such as a copper foil, a silver foil, a gold foil or an aluminum foil with low electrical resistance may be used, and it is preferred to use a copper foil.

The metal layer may be composed of one type of metal, by using one type of metal, or may be composed of multiple types of metal, by using multiple types of metal in combination. As a method of combining multiple types of metal, it is possible to use a method of applying metal plating on a metal foil, and, for example, as the metal foil, a gold-plated copper foil may be used.

Further, depending on the thickness of the metal layer, a carrier-attached metal foil provided with a release layer and a carrier may be used for improving handling efficiency. Furthermore, the metal layer may be a metal foil (raw foil) as being electrolyzed or as being rolled, or it may have surface treatment applied to one surface or both surfaces. As the surface treatment, for example, anti-corrosion treatment, silane treatment, roughening treatment or barrier formation treatment may be mentioned.

As a commercial product of a metal foil to be used as the metal layer, for example, TQ-M4-VSP (trade name, manufactured by Mitsui Mining & Smelting Co., Ltd., copper foil, Rzjis: 0.6 μm, thickness: 18 μm) may be employed.

As the thickness of the metal layer, there is no particular restriction, but it is preferably from 0.1 to 100 μm, more preferably from 0.2 to 50 μm, particularly preferably from 1.0 to 30 μm. When the thickness of the metal layer is within the above preferred range, ordinary wiring patterning methods for wiring boards, such as the MSAP (Modified Semi-Additive) method and the subtractive method, can be easily employed.

As the ten-point average roughness (Rzjis) of the surface on the composition layer side of the metal layer, there is no particular restriction, but it is preferably at most 2.0 μm, more preferably at most 1.0 μm, particularly preferably at most 0.8 μm. These upper limits are preferred from the viewpoint of reducing transmission loss by reducing conductor loss caused by the metal layer, which can increase due to the skin effect of the metal foil when used in the high frequency range. Here, the skin effect refers to a phenomenon in which high-frequency electrical signals flow only near the surface of the metal layer, Because the skin effect causes electrical signals to flow following the unevenness of the metal layer surface, the transmission distance of electrical signals increases with a rougher metal layer, and conductor loss may worsen.

As the ten-point average roughness (Rzjis) of the surface on the composition layer side of the metal foil, there is no particular restriction, but it is preferably at least 0.10 μm, more preferably at least 0.15 μm, particularly preferably at least 0.20 μm. These lower limits are preferred from the viewpoint of improving adhesion between the metal layer and the composition layer or the after-described adhesive layer.

Here, the “ten-point average roughness (Rzjis)” is measured by the same method as in Examples.

The peel strength (degree of adhesion) at the interface between the metal layer and the composition layer or the adhesive layer is preferably at least 8.1 N/cm, more preferably at least 9 N/cm, particularly preferably at least 10 N/cm. Although a higher peel strength is usually preferred, from the viewpoint of mass production of the product, it is preferably at most 30 N/cm, more preferably at most 20 N/cm.

Here, the “peel strength (degree of adhesion)” is measured by the same method as in Examples.

### <Adhesive Layer>

The adhesive layer contains the above-described fluorinated polymer A1 and, as the case requires, an inorganic filler and other component. It is preferred not to contain an inorganic filler with a specific surface area of less than 5.5 m²/g.

The adhesive layer is preferably a layer that functions as a primer layer to improve adhesion between the metal layer and the composition layer.

Here, the fluorinated polymer A1 contained in the adhesive layer is the same as the fluorinated polymer A1 contained in the composition constituting the composition layer. Further, other component that can be contained in the adhesive layer is the same as other component that can be contained in the composition constituting the composition layer.

The specific surface area of the inorganic filler that can be contained in the adhesive layer is preferably at least 5.5 m²/g, more preferably from 5.5 to 30 m²/g, further preferably from 5.5 to 25 m²/g, particularly preferably from 5.5 to 20 m²/g.

When the specific surface area of the inorganic filler in the adhesive layer is within the above preferred range, the adhesive layer thickness can be reduced, and the amount of the inorganic filler to be added can be increased.

Here, the “specific surface area” is measured by the same method as in Examples.

As the median diameter (average particle diameter D50) of the inorganic filler that can be contained in the adhesive layer, there is no particular restriction, and in a certain embodiment, it is preferably less than 1 μm, and in another embodiment, it is preferably from 0.1 to 5 μm, more preferably from 0.1 to 2 μm.

When the median diameter (average particle diameter D50) of the inorganic filler in the adhesive layer is within the above preferred range, it is possible to obtain a thin and homogeneous adhesive layer.

Here, the “median diameter (average particle diameter D50)” is measured by the same method as in Examples.

Here, the inorganic filler that can be contained in the adhesive layer differs from the inorganic filler to be contained in the composition constituting the composition layer only in terms of the specific surface area and the median diameter (average particle diameter D50), and is the same in other respects.

As the content of the inorganic filler in the adhesive layer, there is no particular restriction, but it is preferably at most 85 vol %, more preferably from 40 to 85 vol %, further preferably from 50 to 75 vol %, particularly preferably from 55 to 70 vol %, to the entire volume of the adhesive layer.

When the content of the inorganic filler in the adhesive layer is within the above preferred range, the relative permittivity Dk of the adhesive layer can be brought to be close to Dk of the composition layer.

The thickness of the adhesive layer is, from the viewpoint of reducing transmission loss in the high frequency range and suppressing warpage and delamination, preferably at most 12 μm, more preferably at most 7 μm, particularly preferably at most 4 μm.

Further, as the thickness of the adhesive layer, from the viewpoint of improving adhesion between the metal foil and the composition layer, it is preferably at least 0.1 μm, more preferably at least 0.3 μm, particularly preferably at least 1 μm.

As the dissipation factor Df of the adhesive layer at a frequency of 10 GHz, from the viewpoint of suppressing transmission loss, it is preferably at most 0.003, more preferably at most 0.0025, particularly preferably at most 0.002.

Here, the “dissipation factor Df” is measured by the same method as in Examples.

As the relative permittivity Dk of the adhesive layer at a frequency of 10 GHz, from the viewpoint of easy production and widening the range of options, it is preferably at least 2.0, more preferably at least 2.2, particularly preferably at least 2.4.

Further, as the relative permittivity Dk of the adhesive layer at a frequency of 10 GHz, from the viewpoint of suppressing transmission loss, it is preferably at most 4.0, more preferably at most 3.5, particularly preferably at most 3.2.

Here, the “relative permittivity Dk” is measured by the same method as in Examples.

### <Intermediate Layer>

Further, an intermediate layer may be provided that contains the above-mentioned fluorinated polymer A2, does not contain the above-mentioned fluorinated polymer A1, and, as the case requires, contains other component.

In the case of providing an intermediate layer, it is preferred that it be placed between a composition layer and a composition layer. That is, it is preferably a layer which functions as a layer that divides the composition layer and improves adhesion.

### (Method for Producing Metal-Clad Laminate)

As a method for producing a metal-clad laminate of the present invention, there is no particular restriction, and a conventionally known method can be employed, and, for example, it is possible to employ a method of applying the composition of the present invention to the surface of a metal layer, followed by heating, pressurizing and curing them to obtain a metal-clad laminate. As another method, a laminate molding method may also be used.

Here, the coating equipment to be used for coating, may be suitably selected according to the film thickness of the metal foil to be formed, and, for example, a bar coater, a comma coater, a die coater, a roll coater, a gravure coater, etc. may be mentioned. One type of these may be used alone, or two or more types of these may be used in combination.

As the method for preparing the metal-clad laminate of the present invention by using the after-described resin-attached metal foil, for example, a method of preparing a double-sided metal foil-clad laminate by laminating and integrating two layers of a resin-attached metal foil so that the resin sides face each other by heating and pressure molding, and a method for preparing a double-sided metal foil-clad laminate by laminating and integrating one having a metal foil overlapped on the resin side of a resin-attached metal foil by heating and pressure molding, may be mentioned.

The heating and pressurizing conditions can be suitably set according to the thickness of the laminate to be produced, the type of the composition, etc., and, for example, the temperature can be from 300 to 400° C., the pressure can be from 5 to 10 MPa, and the time can be from 30 to 100 minutes.

There is no particular restriction as to the viscosity at a temperature of 23° C. of the composition to be used in the method for producing the metal-clad laminate, and it is preferably from 10 to 200 mPa·s, more preferably from 20 to 160 mPa·s, particularly preferably from 30 to 120 mPa·s.

When the viscosity at a temperature of 23° C. of the composition is within the above preferred range, the adhesive force between the metal layer and the composition layer can be made to be stronger.

### <Resin-Attached Metal Foil>

FIG. 4 is a schematic cross-sectional view illustrating an example of the resin-attached metal foil to be used at the time of producing a metal-clad laminate of the present invention.

As shown in FIG. 4, the resin-attached metal foil 41 has a structure in which a composition layer 12 made of the composition of the present invention and a metal layer 13 are laminated.

The resin-attached metal foil 41 may have a composition layer 12 made of the composition before curing and a metal layer 13, or it may have a composition layer 12 made of a semi-cured material of the composition and a metal layer 13.

According to the construction as described above, a resin-attached metal foil is obtainable, whereby it is possible to produce a metal-clad laminate having the dielectric loss sufficiently reduced.

As the method for producing the resin-attached metal foil 41, for example, a method of applying the composition to the surface of a metal foil 13 such as a copper foil and then drying it, may be mentioned.

Here, the coating equipment to be used for coating, may be suitable selected according to the film thickness of the metal foil to be formed, and, for example, a bar coater, a comma coater, a die coater, a roll coater, a gravure coater, etc. may be mentioned. One type of these may be used alone, or two or more types of these may be used in combination.

Here, in the resin-attached metal foil of the present invention, the composition or the semi-cured material of the composition may be one having the composition dried or heat-dried.

There is no particular restriction on the conditions for drying or heat-drying in the method of producing the resin-attached metal foil 41, and it is preferred that the heating temperature is from 300 to 400° C. and the heating time is at a level of from 5 to 60 minutes. By such drying or heat-drying, the solvent is volatilized, and the solvent is reduced or removed to obtain the resin-attached metal foil 41 in a pre-cured or semi-cured state.

A wiring circuit is arranged on the surface of the metal-clad laminate of the present invention to produce a wiring substrate. A conventional known method may suitably be used as the method for producing a wiring substrate by forming a wiring circuit on the surface of the metal-clad laminate of the present invention. For example, a subtractive method of etching the metal layer on the surface of the metal-clad laminate of the present invention, or a MSAP method of plating the surface, may be used.

FIG. 5 is a schematic cross-sectional view illustrating an example of the wiring substrate produced by using the metal-clad laminate of the present invention, in which a metal layer 13 arranged via an adhesive layer 14 on one surface of the composition layer 12 is etched (partially removed) to form a wiring circuit 16.

### EXAMPLES

In the following, the present invention will be described in detail with reference to Examples. However, the present invention is not limited by the following Examples.

In the following, the present invention will be specifically described by Ex., but the present invention is not limited by the following description. Here, Ex. 1 to 9, 11 and 14 to 21 are Examples of the present invention, and Ex. 10, 12 and 13 are Comparative Examples.

### <Details of Components Used>

Fluorinated polymer A1: EA-2000 (AGC Inc. product, a fluorinated polymer containing units based on a fluoroolefin and units based on a monomer having an adhesive functional group, melting point by DSC measurement: 300° C.)
Fluorinated polymer A2: Fluon FL1710 (AGC Inc. product, a fluorinated polymer containing units based on polytetrafluoroethylene and fluoroolefin and not containing units based on a monomer having an adhesive functional group)
Inorganic filler B1: FB-950XFC (DENKA Corporation product, spherical silica particles, median diameter (average particle diameter D50): 15.5 μm, specific surface area: 1.7 m²/g, surface adsorbed moisture content: 210 mass ppm)
Inorganic filler B2: FB-25SX (DENKA Corporation product, spherical silica particles, median diameter (average particle diameter D50): 17.3 μm, specific surface area: 3.9 m²/g, surface adsorbed moisture content: 483 mass ppm)
Inorganic filler B3: FB-7SDC (DENKA Corporation product, spherical silica particles, median diameter (average particle diameter D50): 7.6 μm, specific surface area: 1.6 m²/g, surface adsorbed moisture content: 198 mass ppm)
Inorganic filler B4: FB-304 (DENKA Corporation product, spherical silica particles, median diameter (average particle diameter D50): 4.0 μm, specific surface area: 4.0 m²/g, surface adsorbed moisture content: 495 mass ppm)
Inorganic filler B5: FB-950FD (DENKA Corporation product, spherical silica particles, median diameter (average particle diameter D50): 24.2 μm, specific surface area: 1.4 m²/g, sphericity: at least 0.85, surface adsorbed moisture content: 173 mass ppm)
Inorganic filler B6: FB-8C (DENKA Corporation product, spherical silica particles, median diameter (average particle diameter D50): 8.3 μm, specific surface area: 1.6 m²/g, sphericity: at least 0.85, surface adsorbed moisture content: 198 mass ppm)
Inorganic filler B7: FB-7SDX (DENKA Corporation product, spherical silica particles, median diameter (average particle diameter D50): 5.5 μm, specific surface area: 2.4 m²/g, surface adsorbed moisture content: 297 mass ppm)
Inorganic filler B8: FB-302X (DENKA Corporation product, spherical silica particles, median diameter (average particle diameter D50): 5.9 μm, specific surface area: 3.5 m²/g, surface adsorbed moisture content: 433 mass ppm)
Inorganic filler B9: FB-105X (DENKA Corporation product, spherical silica particles, median diameter (average particle diameter 050): 10.3 μm, specific surface area: 3.0 m²/g, surface adsorbed moisture content: 372 mass ppm)
Inorganic filler B101 FB-100XFD (DENKA Corporation product, spherical silica particles, median diameter (average particle diameter D50): 11.4 μm, specific surface area: 5.8 m²/g, surface adsorbed moisture content: 718 mass ppm)
Inorganic filler B11: FB-950XFD (DENKA Corporation product, spherical silica particles, median diameter (average particle diameter D50): 13.0 μm, specific surface area: 2.0 m²/g, surface adsorbed moisture content: 247 mass ppm)
Inorganic filler B12: E-1 (TATSUMORI LTD. product, crushed silica particles, median diameter (average particle diameter D50): 11.0 μm, specific surface area: 1.3 m²/g, surface adsorbed moisture content: 161 mass ppm)

### (Ex. 1 to 21)

A total of 200 g of the respective components listed in the columns for components of the composition in Table 1 and Table 2 given later and 137 g of cyclohexanone were put into a pot and vibrationally mixed by a Resodyn low frequency resonance acoustic mixer (LabMASII) for 20 minutes while applying an acceleration of about 80 G to obtain a slurry-like compositional form.

The above-mentioned slurry was applied by the doctor-blade method in a thickness of 100 μm to the surface of an 18-μm-thick copper foil (TQ-M4-VSP manufactured by Mitsui Mining & Smelting Co., Ltd.), dried for 12 hours under room temperature atmospheric conditions, and then heat-dried at 350° C. for 20 minutes under nitrogen atmosphere, to form a composition layer. Thereby, a single-sided metal-clad laminate having a composition layer and a metal layer made of a copper foil, was obtained.

Two layers of the above-mentioned single-sided metal-clad laminate, laminated so that the resin sides face each other, were pressed in a vacuum hot press apparatus for 60 minutes at a temperature of 330° C. while applying a pressure of 8 MPa to obtain a double-sided metal-clad laminate.

In the obtained double-sided metal-clad laminate, the ratio of the total volume of the polymer and the inorganic filler to the entire volume of the composition layer was 100 vol %, and the thickness of the composition layer was 125 μm.

With respect to the double-sided metal-clad laminate in each Ex., the after-described evaluations were conducted. The results are shown in Table 1 and Table 2.

### <Median Diameter (Average Particle Diameter D50) of Inorganic Filler>

Using a laser diffraction and scattering particle size analyzer (MICROTRAC HRA DHSX100, manufactured by Nikkiso Co., Ltd.), the inorganic filler was dispersed in water and the volume-based particle size distribution was measured to obtain the median diameter (average particle diameter D50).

### <Specific Surface Area of Inorganic Filler>

Using a gas adsorption measuring device (BELSORP MAX, manufactured by MICROTRAC MRB), N₂ gas was adsorbed on the inorganic filler, and from the adsorption behavior, the specific surface area was determined.

### <Sphericity of Inorganic Filler>

Using FPIA-3000, manufactured by SYSMEX CORPORATION, the sphericity of the inorganic filler was measured based on the following calculation formula.
A: Area of particle image
PM: Perimeter of particle image
B: Area of a perfect circle with perimeter of PM
HD: Circle equivalent diameter
Then, the circle equivalent diameter (HD)=(4/π×A)^{1/2}, and
Sphericity=A/B

### <Surface Adsorbed Moisture Content of Inorganic Filler>

Using the CA-200 trace moisture analyzer manufactured by Mitsubishi Chemical Analytech Co., Ltd., the surface adsorbed moisture content of the inorganic filler was measured by the coulometric titration method.

### <Peel Strength>

A rectangular specimen of 100 mm long×10 mm wide was cut out from the after described metal-clad laminate. The copper foil was peeled off from the composition layer up to a position of 10 mm from one end of the specimen in the longitudinal direction. One end of the peeled copper foil was peeled at 90° at a tensile speed of 50 mm/min using a tensile testing machine (Autograph AGS-X manufactured by Shimadzu Corporation), and the load value at which the load became constant with respect to displacement was adopted as the peel strength (N/cm).

Here, in Ex. 13, the peel strength could not be measured accurately because the copper foil peeled off due to the absence of adhesion functional groups in the composition layer, but the measurement result (0.2 N/cm) is noted.

### <Transmission Loss>

A grounded coplanar line (G-CPW) with a line length of 12.5 mm was prepared in the after-described composite CCL, and transmission loss at 80 GHz was measured. The impedance is 50 Ω.

### <Ten-Point Average Roughness Rzjis>

The roughened surface of the copper foil was measured using a Surfcoder SE600 manufactured by Kosaka Laboratory Ltd. in accordance with the method specified in Annex JA of JIS B 0601: 2013.

### <Relative Permittivity Dk and Dissipation Factor Df>

With respect to the composition layer (125 μm thickness), the relative permittivity Dk and the dissipation factor Df were measured at 25° C. and 10 GHz using a cavity resonator and a vector network analyzer in accordance with the method specified in JIS R 1641:2007.

Here, each of the relative permittivity Dk and the dissipation factor Df is often preferably smaller, but may need to be adjusted to a certain value depending on the application.

### (Coefficient of Thermal Expansion)

A 10 mm×10 mm specimen was cut out from the composition layer. With respect to this specimen, the coefficient of thermal expansion CTE (z) in the direction of thickness was measured by using a thereto-mechanical analyzer (manufactured by NETZSCH, TMA402 FA Hyperion). Specifically, the sample was heated over a temperature range of from −20° C. to 240° C. at a rate of 5° C./minute, and the displacement in the thickness of the sample was measured. After the measurement was completed, the coefficient of thermal expansion (CTE) from −20° C. to 240° C. was obtained from the displacement of the sample from −20° C. to 240° C.

TABLE 1

| Ex. | | | 1 | 2 | 3 | 4 | 5 | 6 | 7 |
|---|---|---|---|---|---|---|---|---|---|
| Solid components | Polymer | A1 | 40 | 40 | 40 | 40 | 40 | 40 | 40 |
| of composition | | A2 | — | — | — | — | — | — | — |
| (vol %) | Inorganic filler | B1 | 60 | — | — | — | — | — | — |
| | | B2 | — | 60 | — | — | — | — | — |
| | | B3 | — | — | 60 | — | — | — | — |
| | | B4 | — | — | — | 60 | — | — | — |
| | | B5 | — | — | — | — | 60 | — | — |
| | | B6 | — | — | — | — | — | 60 | — |
| | | B7 | — | — | — | — | — | — | 60 |
| | | B8 | — | — | — | — | — | — | — |
| | | B9 | — | — | — | — | — | — | — |
| | | B10 | — | — | — | — | — | — | — |
| | | B11 | — | — | — | — | — | — | — |
| | | B12 | — | — | — | — | — | — | — |
| Evaluations | Peel strength | | 15.5 | 9.2 | 12.6 | 10.2 | 19.3 | 10.4 | 14.4 |
| | (N/cm) | | | | | | | | |
| | Transmission loss | | −0.4 | −0.4 | −0.4 | −0.4 | −0.4 | −0.4 | −0.4 |
| | (dB/cm) | | | | | | | | |
| | Ten-point average roughness | | 0.6 | 0.6 | 0.6 | 0.6 | 0.6 | 0.6 | 0.6 |
| | (μm) | | | | | | | | |
| | Dissipation factor | | 0.001 | 0.001 | 0.001 | 0.001 | 0.001 | 0.001 | 0.001 |
| | Df | | | | | | | | |
| | Relative permittivity | | 2.75 | 2.75 | 2.75 | 2.75 | 2.75 | 2.75 | 2.75 |
| | Dk | | | | | | | | |
| Ex. | | | 8 | 9 | 10 | 11 | 12 | 13 | 14 |
| Solid components | Polymer | A1 | 40 | 40 | 40 | 40 | 50 | — | 20 |
| of composition | | A2 | — | — | — | — | | 40 | 20 |
| (vol %) | Inorganic filler | B1 | — | — | — | — | — | — | — |
| | | B2 | — | — | — | — | — | — | — |
| | | B3 | — | — | — | — | — | — | 60 |
| | | B4 | — | — | — | — | — | — | — |
| | | B5 | — | — | — | — | — | — | — |
| | | B6 | — | — | — | — | — | — | — |
| | | B7 | — | — | — | — | — | — | — |
| | | B8 | 60 | — | — | — | — | — | — |
| | | B9 | — | 60 | — | — | — | — | — |
| | | B10 | — | — | 60 | — | — | — | — |
| | | B11 | — | — | — | 60 | — | — | — |
| | | B12 | — | — | — | — | 50 | 60 | — |

| | | | | | | | | |
|---|---|---|---|---|---|---|---|---|
| Evaluations | Peel strength | 8.4 | 11.2 | 8.0 | 17.7 | 8.5 | 0.2 | 9.0 |
| | (N/cm) | | | | | | | |
| | Transmission loss | −0.4 | −0.4 | −0.4 | −0.4 | — | — | −0.4 |
| | (dB/cm) | | | | | | | |
| | Ten-point average roughness | 0.6 | 0.6 | 0.6 | 0.6 | 0.6 | 0.6 | 0.6 |
| | (μm) | | | | | | | |
| | Dissipation factor | 0.001 | 0.001 | 0.001 | 0.001 | 0.001 | 0.0008 | 0.0008 |
| | Df | | | | | | | |
| | Relative permittivity | 2.75 | 2.75 | 2.75 | 2.75 | 2.75 | 2.75 | 2.75 |
| | Dk | | | | | | | |

TABLE 2

| Ex. | | | 15 | 16 | 17 | 18 | 19 | 20 | 21 |
|---|---|---|---|---|---|---|---|---|---|
| Solid components | Polymer | A1 | 40 | 37 | 35 | 33 | 35 | 33 | 35 |
| of composition | | A2 | — | — | — | — | — | — | — |
| (vol %) | Inorganic filler | B1 | — | — | — | — | — | — | — |
| | | B2 | — | — | — | — | — | — | — |
| | | B3 | — | — | — | — | 65 | 67 | — |
| | | B4 | — | — | — | — | — | — | — |
| | | B5 | — | — | — | — | — | — | — |
| | | B6 | — | 63 | 65 | 67 | — | — | — |
| | | B7 | — | — | — | — | — | — | 65 |
| | | B8 | — | — | — | — | — | — | — |
| | | B9 | — | — | — | — | — | — | — |
| | | B10 | — | — | — | — | — | — | — |
| | | B11 | — | — | — | — | — | — | — |
| | | B12 | 60 | — | — | — | — | — | — |

| | | | | | | | | |
|---|---|---|---|---|---|---|---|---|
| Evaluations | Peel strength | 8.2 | 9.3 | 8.9 | 8.4 | 8.5 | 8.1 | 8.4 |
| | (N/cm) | | | | | | | |
| | Transmission loss | −0.4 | −0.4 | −0.4 | −0.4 | −0.4 | −0.4 | −0.4 |
| | (dB/cm) | | | | | | | |
| | Ten-point average roughness | 0.6 | 0.6 | 0.6 | 0.6 | 0.6 | 0.6 | 0.6 |
| | (μm) | | | | | | | |
| | Dissipation factor | 0.001 | 0.001 | 0.001 | 0.0009 | 0.001 | 0.0009 | 0.001 |
| | Df | | | | | | | |
| | Relative permittivity | 2.8 | 2.85 | 2.9 | 2.87 | 2.9 | 2.85 | 2.89 |
| | Dk | | | | | | | |

The peel strengths in Ex. 1 to 9, 11, 12 and 14 to 21 were from 8.1 to 19.3 (N/cm), all higher than the peel strength 8.0 (N/cm) in Ex. 10. Among these, the peel strengths in Ex. 1 (15.5 N/cm), Ex. 5 (19.3 N/cm) and Ex, 11 (17.7 N/cm) were particularly high and good.

The transmission losses in Ex. 1 to 11 and 14 to 21 were −0.4 dB/cm.

The transmission loss in Ex. 12 was not measurable because the CTE of the composition layer was too high to form a transmission line.

The transmission loss in Ex. 13 was not measurable because the copper foil peeling strength was too weak to form a transmission line.

The ten-point average roughnesses of the roughened surfaces of the copper foils in Ex. 1 to 21 were each 0.6 μm.

The dissipation factors Df in Ex, 1 to 12, 15 to 17, 19 and 21 were each 0.001. The dissipation factors Df in Ex. 13 and 14 were each 0.0008.

The dissipation factors Df in Ex. 18 and 20 were each 0.0009,

The relative permittivities Dk in Ex. 1 to 14 were each 2.75.

The relative permittivities Dk in Ex, 15 to 21 were from 2.8 to 2.9.

From the foregoing, it was found that by using a composition comprising a fluorinated polymer A1 containing units based on a fluoroolefin and units based on a monomer having an adhesive functional group, and an inorganic filler having a specific surface area of less than 5.5 m²/g, and wherein the content of the inorganic filler in the solid content of the composition is at least 55 vol %, to the entire volume of the solid content of the composition, it is possible to obtain a metal-clad laminate in which the specific permittivity and the dissipation factor are low and the adhesiveness of the composition layer to the metal layer is improved.

In addition, it was found that in the above composition, if a fluorinated polymer containing units based on a fluoroolefin and not containing units based on a monomer having an adhesive functional group, is used instead of the fluorinated polymer A1 containing units based on a fluoroolefin and units based on a monomer having an adhesive functional group, a sufficient peel strength cannot be obtained, and the transmission loss becomes to be not measurable. (See the comparison between Ex. 15 and Ex. 13).

Furthermore, in the above composition, by increasing the content of the inorganic filler in the solid content of the composition to at least 63 vol %, it is possible to adjust so that the value of the relative permittivity Dk becomes to be large without increasing the value of the dissipation factor Df. (See comparison between Ex. 6 and Ex. 16 to 18, comparison between Ex. 3 and Ex. 19 to 20, and comparison between Ex. 7 and Ex. 21.)

### INDUSTRIAL APPLICABILITY

The present invention has a wide range of industrial applicability in the technical fields related to electronic materials and various devices using them.

### REFERENCE SYMBOLS

11, 21, 31: Metal-clad laminate
12: Composition layer (insulating layer)
13: Metal layer
14: Adhesive layer (primer layer)
15: Intermediate layer
16: Wiring circuit
41: Resin-attached metal foil

This application is a continuation of PCT Application No. PCT/JP2022/022650, filed on Jun. 3, 2022, which is based upon and claims the benefit of priority from Japanese Patent Application No. 2021-097909, filed on Jun. 11, 2021. The contents of those applications are incorporated herein by reference in their entireties.

What is claimed is:

1. A composition comprising a fluorinated polymer A1 containing units based on a fluoroolefin and units based on a monomer having an adhesive functional group, and an inorganic filler having a specific surface area of less than 5.5 m²/g, wherein
the content of the inorganic filler in the solid content of the composition is at least 55 vol % to the entire volume of the solid content of the composition.

2. The composition according to claim 1, which further comprises a fluorinated polymer A2 containing units based on a fluoroolefin and not containing units based on a monomer having an adhesive functional group.

3. The composition according to claim 2, wherein the content of the fluorinated polymer A2 is at least 10 vol % to the total of the fluorinated polymer A1 and the fluorinated polymer A2.

4. The composition according to claim 1, wherein the adhesive functional group is at least one type selected from the group consisting of a carbonyl group, a hydroxy group, an epoxy group, an amide group, an amino group and an isocyanate group.

5. The composition according to claim 1, wherein the inorganic filler is at least one of silicon oxide and titanium oxide.

6. The composition according to claim 1, wherein the inorganic filler has a sphericity of at least 0.80.

7. The composition according to claim 1, wherein the median diameter (average particle size D50) of the inorganic filler is less than 20 μm.

8. The composition according to claim 1, wherein the content of the inorganic filler in the solid content of the composition is at most 85 vol % to the entire volume of the solid content of the composition.

9. The composition according to claim 1, wherein the surface adsorbed moisture content of the inorganic filler is at most 500 mass ppm.

10. A metal-clad laminate, comprising a composition layer made of the composition as defined in claim 1, and a metal layer.

11. The metal-clad laminate according to claim 10, which further comprises an adhesive layer containing the fluorinated polymer A1 and containing no inorganic filler having a specific surface area of less than 5.5 m²/g.

12. The metal-clad laminate according to claim 11, wherein the adhesive layer further contains an inorganic filler having a specific surface area of at least 5.5 m²/g, and the content of the inorganic filler to the entire volume of the adhesive layer is at most 85 vol % to the entire volume of the adhesive layer.

13. The metal-clad laminate according to claim 10, wherein the metal layer is a layer made of a copper foil.

14. The metal-clad laminate according to claim 10, wherein the ten-point average roughness (Rzjis) of the surface on the composition layer side of the metal layer is at most 2.0 μm.

15. A method for producing a metal-clad laminate, which comprises applying the composition as defined in claim 1 to the surface of a metal layer to obtain a metal-clad laminate.
